(19) United States
(12) Patent Application Publication
(10) Pub. No.: US 2010/0093180 A1
(43) Pub. Date: Apr. 15, 2010

(54) METHOD OF FABRICATING SEMICONDUCTOR DEVICE

(76) Inventor: Eimei NAKAYAMA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/491,099

(22) Filed: Jun. 24, 2009

(30) Foreign Application Priority Data
Oct. 10, 2008 (JP) 2008-263557

(51) Int. Cl. H01L 21/306

(52) U.S. Cl. 438/735; 438/745; 257/E21.215

(57) ABSTRACT

A method of fabricating a semiconductor device according to one embodiment includes: forming a first opening pattern and a second opening pattern larger in size than the first opening pattern in a first film formed above a semiconductor substrate and in a second film on the first film, the second film comprising a material different from the first film; forming a blocking film on the second film, the blocking film substantially blocking only the first opening pattern between the first and second opening patterns of the second film; and selectively applying isotropic etching to an inner side face of the second opening pattern of the first film after forming the blocking film, thereby enlarging only the size of the second opening pattern between the size of the first opening pattern and the size of the second opening pattern of the first film.

### CROSS-REFERENCE TO RELATED APPLICATIONS

This application is based upon and claims the benefit of priority from prior Japanese Patent Application No. 2008-263557, filed on Oct. 10, 2008, the entire contents of which are incorporated herein by reference.

### BACKGROUND

As a method of forming a pattern on a workpiece material, there is a method in which etching is applied to the workpiece member using a resist film having a predetermined pattern formed by a photolithography method as a mask. Here, when a pattern to be formed in the workpiece material is microscopic, a dimension conversion difference (a dimensional difference between a photomask pattern and a pattern actually formed in a workpiece film) is generated, hence, it is required to correct the dimension conversion difference in order to form a pattern in an accurate dimension on a workpiece film.

In general, the dimension conversion difference differs according to a size of an opening pattern for the following reasons. The larger the size of the opening pattern is, the more likely it is that the etching reaction product attaches on a side face of the pattern, thus, a size of a pattern actually formed on the workpiece film becomes small, i.e., the dimension conversion difference becomes large.

From this point of view, a method is also known in which a side face of a dense pattern is prevented from being side etched while correcting the dimension conversion difference of a sparse pattern by controlling etching conditions for adjusting an attached amount of the reaction product on side faces of the dense pattern and the sparse pattern. This method, for example, is disclosed in JP-A 2008-78582.

However, as long as trying to simultaneously form the dense pattern and the sparse pattern having different dimensions, there is a problem in that it is extremely difficult to derive appropriate etching conditions which allow an accurate correction of the dimension conversion difference with respect to any opening patterns.

### BRIEF SUMMARY

A method of fabricating a semiconductor device according to one embodiment includes: forming a first opening pattern and a second opening pattern larger in size than the first opening pattern in a first film formed above a semiconductor substrate and in a second film on the first film, the second film comprising a material different from the first film; forming a blocking film on the second film, the blocking film substantially blocking only the first opening pattern between the first and second opening patterns of the second film; and selectively applying isotropic etching to an inner side face of the second opening pattern of the first film after forming the blocking film, thereby enlarging only the size of the second opening pattern between the size of the first opening pattern and the size of the second opening pattern of the first film.

A method of fabricating a semiconductor device according to another embodiment includes: forming a first opening pattern and a second opening pattern larger in size than the first opening pattern in a workpiece film formed above a semiconductor substrate; forming a blocking film on the workpiece film, the blocking film substantially blocking only the first opening pattern between the first and second opening patterns of the workpiece film; applying isotropic etching to a portion of an inner side face of the second opening pattern of the workpiece film for enlarging only the size of the second opening pattern between the size of the first opening pattern and second opening pattern of the workpiece film, the portion being not covered by the blocking film; and removing the blocking film and a region of an upper portion of the workpiece film, the region including a portion that was covered by the blocking film on the inner side face of the second opening pattern.

### BRIEF DESCRIPTION OF THE DRAWING

FIGS. 1A to 1H are cross sectional views showing processes for fabricating a semiconductor device according to a first embodiment;

FIGS. 2A and 2B are a top view schematically showing an SRAM cell and a cross sectional view thereof, respectively; and

FIGS. 3A to 3E are cross sectional views showing processes for fabricating a semiconductor device according to a second embodiment

### DETAILED DESCRIPTION

### First Embodiment

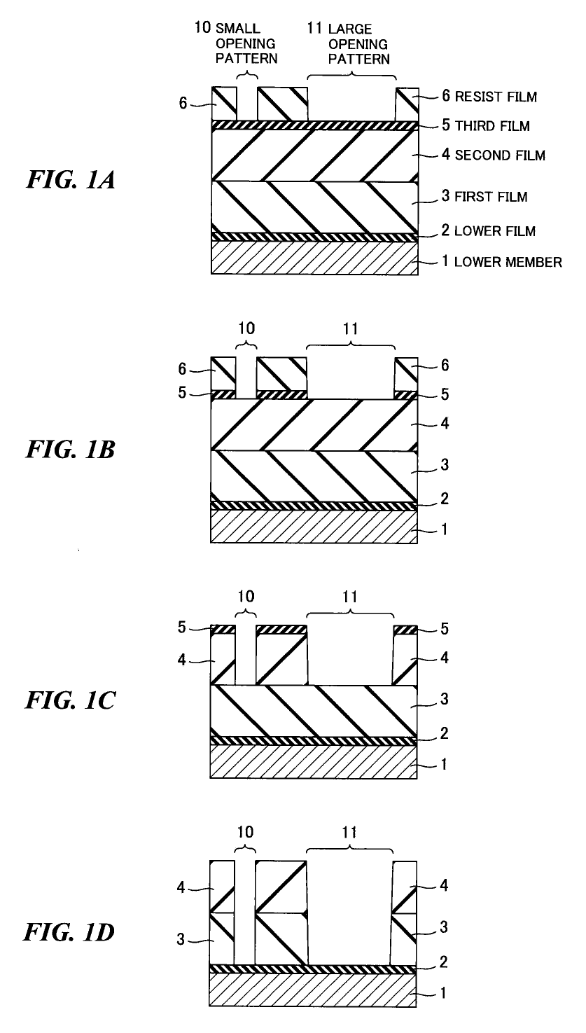

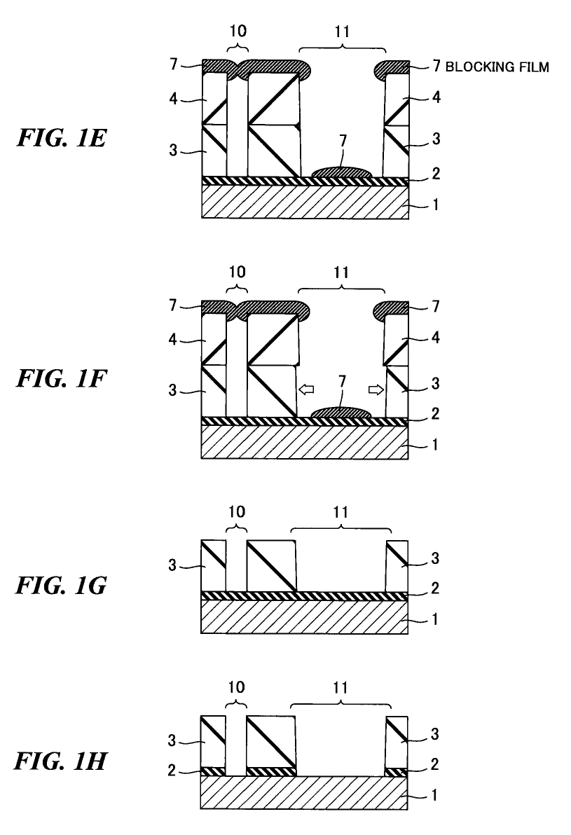

FIGS. 1A to 1H are cross sectional views showing processes for fabricating a semiconductor device according to a first embodiment.

Firstly, as shown in FIG. 1A, a lower film 2, a first film 3, a second film 4 and a third film 5 are laminated on a lower member 1 composed of, e.g., a semiconductor substrate having a non-illustrated semiconductor element formed thereon, etc., and a resist film 6 having a small opening pattern 10 and a large opening pattern 11 formed thereon is formed on the third film 5.

Here, the lower film 2, the first film 3, the second film 4 and the third film 5 are respectively made of, e.g., SiN, SiO₂ (including the SiO₂ using TEOS (Tetraethoxysilane) as a raw material), a resist material such as an organic film, etc., and SiO₂, and are formed by a CVD (Chemical Vapor Deposition) method or a coating method, etc. The type of etching gas used for etching each film described in the following explanation for the process is used in case that the lower film 2, the first film 3, the second film 4 and the third film 5 are respectively made of, e.g., SiN, SiO₂, a resist material such as an organic film, etc., and SiO₂.

The resist film 6 is made of a resist material, etc., such as an organic film, etc., and after the film formation thereof by the coating method, etc., the resist film 6 is patterned by a photolithography method. The resist film 6 is preferably formed thinner than the second film 4.

Next, as shown in FIG. 1B, the third film 5 is etched using the resist film 6 as a mask, thereby transferring the small opening pattern 10 and the large opening pattern 11 to the third film 5. At this time, for example, a CF₄/CH₂F₂ mixture gas is used as an etching gas.

Next, as shown in FIG. 1C, the second film 4 is etched using the resist film 6 and the third film 5 as a mask, thereby transferring the small opening pattern 10 and the large opening pattern 11 to the second film 4. At this time, for example, a N₂/O₂/CH₄ mixture gas is used as an etching gas.

Note that, the resist film 6 disappears during the etching, and eventually, the third film 5 functions as a mask.

Next, as shown in FIG. 1D, the first film 3 is etched using the third film 5 and the second film 4 as a mask, thereby transferring the small opening pattern 10 and the large opening pattern 11 to the first film 3. At this time, for example, a C₄F₈/C₄F₆/Ar/O₂ mixture gas is used as an etching gas.

Note that, the third film 5 disappears during the etching, and eventually, the second film 4 functions as a mask.

Here, since the small opening pattern 10 is small in size, there is substantially no difference in size between a pattern on the photomask and the pattern formed on the first film 3. On the other hand, since the large opening pattern 11 is large in size and the etching reaction product is likely to attach on a side face of the pattern of each film, the size of the pattern formed on the first film 3 becomes smaller than that on the photomask.

Next, as shown in FIG. LE, a blocking film 7 which is a C-containing film using a C-containing gas as a raw material is deposited on the second film 4. At this time, the blocking film 7 substantially blocks only the small opening pattern 10 between the small opening pattern 10 and the large opening pattern 11 of the second film 4. The substantial block means the sufficient block for preventing entrance of the etching gas into the inside of the small opening pattern 10 of the second film 4 and of the first film 3.

On the other hand, since the large opening pattern 11 is larger in size than the small opening pattern 10, although the size of the large opening pattern 11 is narrowed by the blocking film 7 protruding from a rim of the large opening pattern 11 toward the inside thereof, it does not result in blocking the large opening pattern 11. Note that, as shown in FIG. 1E, a portion of the blocking film 7 may enter inside the large opening pattern 11 of the second film 4 and of the first film 3.

The blocking film 7 is, e.g., a fluorocarbon-containing film produced by plasma using a fluorocarbon mixture gas, such as CF₄/CH₄ mixture gas, etc., as a C-containing gas and can be deposited in the same chamber used for carrying out the etching shown in FIGS. 1A to 1D. In this case, it is preferable that there is more C than F in plasma during the film formation of the blocking film 7.

Next, as shown in FIG. 1F, the first film 3 is selectively removed from the inner side of the large opening pattern 11 by isotropic etching for enlarging the size of large opening pattern 11 of the first film 3. Thus, the size of the large opening pattern 11 of the first film 3 is corrected so as to substantially match the pattern size of the photomask. At this time, for example, a gas containing hydrogen fluoride such as a HF/H₂O mixture gas is used as an etching gas, and when this process is performed in the same chamber used for carrying out the etching shown in FIGS. 1A to 1D, the etching is carried out under a condition in which self-bias voltage applied to the substrate decreases such that the first film 3 is isotropically etched. Concretely, if a multi-frequency superimposed etching equipment which supplies power of two frequencies, high and low frequencies, is used, the etching condition is only set to reduce the power of the low-frequency side.

Note that, when the first film 3 is made of a material other than SiO₂, an etching gas which can isotropically etch the material is used. Alternatively, the size of the large opening pattern 11 of the first film 3 may be enlarged by wet etching. In this case, as for an etchant, for example, a chemical solution such as hydrofluoric acid can be used when the first film 3 is made of SiO₂, and hot phosphoric acid can be used when the first film 3 is made of SiN.

At this time, since the blocking film 7 blocks the small opening pattern 10 of the second film 4, the entrance of the etching gas into the inside of the small opening pattern 10 of the second film 4 and of the first film 3 is prevented, thus, the size of the small opening pattern 10 of the first film 3 does not change. In other words, it can be avoided that excessive size correction in accordance with a dimension conversion difference of the large opening pattern 11 is performed to the small opening pattern 10.

Next, as shown in FIG. 1G, the blocking film 7 and the second film 4 are removed by etching. At this time, for example, an O₂ gas is used as an etching gas, and this process also can be performed in the same chamber used for carrying out the etching shown in FIGS. 1A to 1D.

Next, as shown in FIG. 1H, the lower film 2 is etched using the first film 3 as a mask, thereby transferring the small opening pattern 10 and the dimensionally corrected large opening pattern 11 to the lower film 2. At this time, for example, a CH₃F/O₂ gas is used as an etching gas.

### Effect of the First Embodiment

According to the first embodiment, between the size of the small opening pattern 10 and the size of the large opening pattern 11, only the size of the large opening pattern 11 in which the dimension conversion difference thereof with the photomask becomes larger during the etching shown in FIGS. 1A to 1D is corrected, and it is thereby possible to simultaneously form both of the small opening pattern 10 and the large opening pattern 11 in an accurate dimension in the first film 3 and the lower film 2.

As an example of the application of the present embodiment to a semiconductor device, an application thereof to a semiconductor device having a 6-transistor type SRAN will be explained hereinafter.

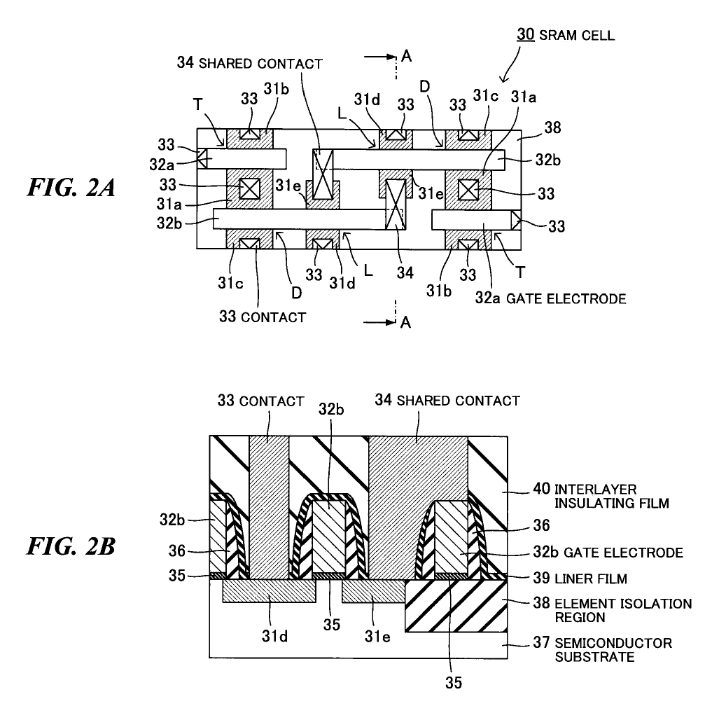

FIG. 2A is a top view schematically showing a 6-transistor type SRAM cell. In addition, FIG. 2B is a cross sectional view of the SRAM cell when a cut surface taken on line A-A of FIG. 2 is viewed in a direction indicated by an arrow. Note that, a range of a cross section shown in FIG. 2B includes a portion of the SRAM cell adjacent to the SRAM cell shown in FIG. 2A in an upward direction of the figure.

A 6-transistor type SRAM cell 30 includes three types of transistors, which are an n-type transfer transistor T, an n-type driver transistor D and a p-type load transistor L, source/drain regions 31a, 31b, 31c, 31d and 31e, gate electrodes 32a and 32b, contacts 33 connected to the source/drain regions 31a, 31b, 31c, 31d and the gate electrode 32a, a shared contact 34 commonly connected to the gate electrode 32b and the source/drain region 31e, gate insulating films 35 formed under the gate electrodes 32a and 32b, and gate sidewalls 36 formed on side faces of the gate electrodes 32a and 32b.

In addition, the transfer transistor T, the driver transistor D and the load transistor L are formed on a semiconductor substrate 37, and are electrically isolated from each other by an element isolation region 38.

A liner film 39 and an interlayer insulating film 40 are formed on the semiconductor substrate 37 provided with the transfer transistor T, the driver transistor D and the load transistor L. The contact 33 and the shared contact 34 are formed by embedding a conductive material into trenches formed in the interlayer insulating film 40 and the liner film 39.

Since the shared contact 34 is commonly connected to the gate electrode 32b shared by the driver transistor D and the load transistor L and to the source/drain region 31e belonging to the load transistor L, a cross-section area of the shared contact 34 in a horizontal direction is larger than that of the contact 33. Therefore, the trench formed in the interlayer insulating film 40 for the shared contact 34 has an opening size larger than that of the trench for the contact 33.

The trench for the shared contact 34 and the trench for the contact 33 having different opening sizes can be simultaneously formed in an accurate size in the interlayer insulating film 40 and the liner film 39 by applying the first embodiment. In this case, the small opening pattern 10 in the first embodiment corresponds to a pattern of the trench for the contact 33, the large opening pattern 11 corresponds to a pattern of the trench for the shared contact 34, and the first film 3 and the lower film 2 correspond to the interlayer insulating film 40 and the liner film 39, respectively.

### Second Embodiment

The second embodiment is different from the first embodiment in a position for forming the blocking film 7. Note that, the explanation will be omitted or simplified for the points same as the first embodiment.

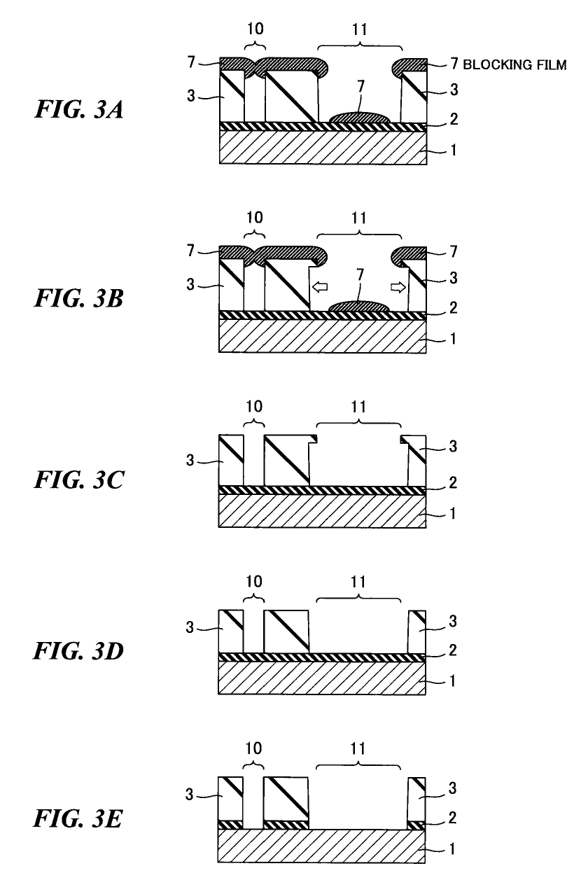

FIGS. 3A to 3E are cross sectional views showing processes for fabricating a semiconductor device according to a second embodiment.

Firstly, the processes until the process, shown in FIGS. 1A to 1D, for transferring the small opening pattern 10 and the large opening pattern 11 to the first film 3 are carried out in the same way as the first embodiment. After that, the second film 4 is removed by etching using an O₂ gas, etc.

Next, as shown in FIG. 3A, the a blocking film 7 which is a C-containing film using a C-containing gas as a raw material is deposited on the first film 3 in the same way as the first embodiment. At this time, the blocking film 7 substantially blocks only the small opening pattern 10 between the small opening pattern 10 and the large opening pattern 11 of the first film 3.

On the other hand, since the large opening pattern 11 is larger in size than the small opening pattern 10, although the opening of the large opening pattern 11 is narrowed by the blocking film 7 protruding from a rim of the large opening pattern 11 toward the inside thereof, it does not result in blocking the large opening pattern 11. Note that, as shown in FIG. 3A, a portion of the blocking film 7 may enter inside the large opening pattern 11 of the first film 3.

Next, as shown in FIG. 3B, the first film 3 is selectively removed from the inner side of the large opening pattern 11 by the same isotropic etching as the first embodiment for enlarging the size of large opening pattern 11 of the first film 3. Thus, the size of the large opening pattern 11 of the first film 3 is corrected so as to substantially match the pattern size of the photomask. Note that, since the etching does not reach an upper portion of the inner side face of the large opening pattern 11 covered by the blocking film 7, a pattern size of a region including this portion is not corrected.

At this time, since the blocking film 7 blocks the small opening pattern 10 of the first film 3, the entrance of the etching gas into the inside of the small opening pattern 10 of the first film 3 is prevented, thus, the size of the small opening pattern 10 of the first film 3 does not change. In other words, it can be avoided that excessive size correction in accordance with a dimension conversion difference of the large opening pattern 11 is performed to the small opening pattern 10.

Next, as shown in FIG. 3C, the blocking film 7 is removed by etching in the same way as the first embodiment. At this time, for example, an O₂ gas is used as an etching gas.

Next, as shown in FIG. 3D, anisotropic etching such as RIE (Reactive Ion Etching), etc., or planarization treatment such as CMP (Chemical Mechanical Polishing), etc., is applied to the first film 3 for removing an upper portion of the first film 3 which was covered by the blocking film 7 on an upper portion of the inner side face of the large opening pattern 11, i.e., a region including a portion to which a size correction is not carried out.

Next, as shown in FIG. 3E, the lower film 2 is etched using the first film 3 as a mask, thereby transferring the small opening pattern 10 and the dimensionally corrected large opening pattern 11 to the lower film 2.

### Effect of the Second Embodiment

According to the second embodiment, similarly to the first embodiment, between the size of the small opening pattern 10 and the size of the large opening pattern 11, only the size of the large opening pattern 11 in which the dimension conversion difference thereof with the photomask is large is corrected, and it is thereby possible to simultaneously form both of the small opening pattern 10 and the large opening pattern 11 in an accurate dimension in the first film 3 and the lower film 2.

It should be noted that the present invention is not intended to be limited to the above-mentioned first and second embodiments, and the various kinds of changes thereof can be implemented by those skilled in the art without departing from the gist of the invention. For example, although the application to the formation of the contact and the shared contact of the SRAM cell has been explained in the first embodiment, it is not limited thereto practically, and it is possible to apply to the method of fabricating various types of semiconductor devices including a process of forming opening patterns having different sizes.

In addition, the constituent elements of the above-mentioned embodiments can be arbitrarily combined with each other without departing from the gist of the invention.

What is claimed is:

1. A method of fabricating a semiconductor device, comprising:
forming a first opening pattern and a second opening pattern larger in size than the first opening pattern in a first film formed above a semiconductor substrate and in a second film on the first film, the second film comprising a material different from the first film;
forming a blocking film on the second film, the blocking film substantially blocking only the first opening pattern between the first and second opening patterns of the second film; and
selectively applying isotropic etching to an inner side face of the second opening pattern of the first film after forming the blocking film, thereby enlarging only the size of the second opening pattern between the size of the first opening pattern and the size of the second opening pattern of the first film.

2. The method of fabricating a semiconductor device according to claim 1, wherein the blocking film is a carbon-containing film.

3. The method of fabricating a semiconductor device according to claim 2, wherein the blocking film is formed by plasma using a carbon-containing gas.

4. The method of fabricating a semiconductor device according to claim 1, wherein the blocking film is a film containing fluorocarbon.

5. The method of fabricating a semiconductor device according to claim 4, wherein the blocking film is formed by plasma using a fluorocarbon mixture gas.

6. The method of fabricating a semiconductor device according to claim 1, wherein the first film comprises SiO₂; and
the isotropic etching is carried out using a gas containing hydrogen fluoride or a chemical solution containing hydrogen fluoride.

7. The method of fabricating a semiconductor device according to claim 6, wherein the second film comprises a resist material.

8. The method of fabricating a semiconductor device according to claim 1, wherein formation of the first and second opening patterns in the first and second films and formation of the blocking film are carried out in the same chamber.

9. The method of fabricating a semiconductor device according to claim 8, wherein formation of the first and second opening patterns in the first and second films, formation of the blocking film and a size enlargement of the second opening pattern of the first film are carried out in the same chamber.

10. The method of fabricating a semiconductor device according to claim 9, further comprising:
removing the blocking film and the second film after the size enlargement of the second opening pattern of the first film,
wherein formation of the first and second opening patterns in the first and second films, formation of the blocking film, a size enlargement of the second opening pattern of the first film and a removal of the blocking film and the second film are carried out in the same chamber.

11. The method of fabricating a semiconductor device according to claim 1, wherein the first film is an interlayer insulating film formed on an SRAM cell via a liner film, the SRAM cell being formed on the semiconductor substrate; and
the first and second opening patterns respectively correspond to a contact pattern and a shared contact pattern to be formed in the liner film and the interlayer insulating film.

12. A method of fabricating a semiconductor device, comprising:
forming a first opening pattern and a second opening pattern larger in size than the first opening pattern in a workpiece film formed above a semiconductor substrate;
forming a blocking film on the workpiece film, the blocking film substantially blocking only the first opening pattern between the first and second opening patterns of the workpiece film;
applying isotropic etching to a portion of an inner side face of the second opening pattern of the workpiece film for enlarging only the size of the second opening pattern between the size of the first opening pattern and second opening pattern of the workpiece film, the portion being not covered by the blocking film; and
removing the blocking film and a region of an upper portion of the workpiece film, the region including a portion that was covered by the blocking film on the inner side face of the second opening pattern.

13. The method of fabricating a semiconductor device according to claim 12, wherein the blocking film is a carbon-containing film.

14. The method of fabricating a semiconductor device according to claim 13, wherein the blocking film is formed by plasma using a carbon-containing gas.

15. The method of fabricating a semiconductor device according to claim 12, wherein the blocking film is a film containing fluorocarbon.

16. The method of fabricating a semiconductor device according to claim 15, wherein the blocking film is formed by plasma using a fluorocarbon mixture gas.

17. The method of fabricating a semiconductor device according to claim 12, wherein the workpiece film comprises SiO₂; and
the isotropic etching is carried out using a gas containing hydrogen fluoride or a chemical solution containing hydrogen fluoride.

18. The method of fabricating a semiconductor device according to claim 17, wherein the region of the upper portion of the workpiece film is removed by anisotropic etching or planarization treatment.

19. The method of fabricating a semiconductor device according to claim 12, wherein formation of the first and second opening patterns in the workpiece film and formation of the blocking film are carried out in the same chamber.

20. The method of fabricating a semiconductor device according to claim 13, wherein the workpiece film is an interlayer insulating film formed on an SRAM cell via a liner film, the SRAM cell being formed on the semiconductor substrate; and
the first and second opening patterns respectively correspond to a contact pattern and a shared contact pattern to be formed in the liner film and the interlayer insulating film.
